(19) United States
(12) Patent Application Publication
(10) Pub. No.: US 2026/0310085 A1
(43) Pub. Date: Oct. 8, 2026

(54) HIGH CHI BLOCK COPOLYMER (BCP) PATTERN ON LATENT EXTREME ULTRAVIOLET (EUV) IMAGES

(71) Applicant: Applied Materials, Inc., Santa Clara, CA (US)

(72) Inventors: RUDY WOJTECKI, East Garrison, CA (US); SIVANANDHA KANAKASABAPATHY, Pleasanton, CA (US)

(21) Appl. No.: 19/098,900

(22) Filed: Apr. 2, 2025

(51) Int. Cl. G03F 7/20; G03F 7/004

(52) U.S. Cl. CPC G03F 7/202; G03F 7/0041; G03F 7/0043

(57) ABSTRACT

Embodiments described herein relate to a method of patterning a polarity switching layer that includes applying a block copolymer over the polarity switching layer, and annealing the block copolymer to generate a polar region and a non-polar region of the block copolymer. In an embodiment, a chemical difference between a first region of the polarity switching layer and a second region of the polarity switching layer allows for directed self-assembly of the polar region of the block copolymer and the non-polar region of the block copolymer over the polarity switching layer. In an embodiment, the method may further include selectively removing either the polar region or the non-polar region to form a patterned mask over the polarity switching layer. In an embodiment, the method may further include patterning the polarity switching layer with an etching process using the patterned mask.

### BACKGROUND

### 1) Field

Embodiments relate to the field of semiconductor manufacturing and, in particular, patterning a resist layer using directed self-assembly (DSA) with high chi block copolymers (BCPs).

### 2) Description of Related Art

Extreme ultraviolet (EUV) photoresists allow for the continued scaling to smaller features that are patterned on a semiconductor substrate. In an EUV lithography process, EUV radiation is selectively applied to regions of the photoresist layer in order to generate a solubility switch that enables the formation of a latent image within the photoresist layer. The latent image corresponds to the portions of the photoresist layer that have undergone the solubility switch as a result of a chemical reaction that is induced by the EUV exposure. After the latent image is produced within the photoresist layer, a developing process may be used in order to generate a pattern in the photoresist layer.

As minimum feature sizes continue to decrease, the thickness of the EUV resist is also decreasing. Particularly, as the numerical aperture (NA) of lithography systems continue to decease (e.g., NAs of 0.33 and below), the thickness of the EUV resist may need to be reduced to 25 nm or less for chemically amplified resists (CARs) or 15 nm or less for metal oxide resists (MORs). The decrease in thickness may render the EUV resist more susceptible to profile variation and/or modification during etching (e.g., due to outgassing and/or stress). Additionally, resist layers with smaller thickness require a higher etch resistance relative to an underlying hardmask in order to preserve the fidelity of the patterned features (e.g., with respect to line edge roughness (LER) and/or local critical dimension uniformity (LCDU)).

### SUMMARY

Embodiments described herein relate to a method of patterning a polarity switching layer that includes applying a block copolymer over the polarity switching layer, and annealing the block copolymer to generate a polar region and a non-polar region of the block copolymer. In an embodiment, a chemical difference between a first region of the polarity switching layer and a second region of the polarity switching layer allows for directed self-assembly of the polar region of the block copolymer and the non-polar region of the block copolymer over the polarity switching layer. In an embodiment, the method may further include selectively removing either the polar region or the non-polar region to form a patterned mask over the polarity switching layer. In an embodiment, the method may further include patterning the polarity switching layer with an etching process using the patterned mask.

Embodiments described herein relate to a method for patterning an exposed polarity switching layer that is over a substrate, where the exposed polarity switching layer includes an exposed region and an unexposed region. In an embodiment, the method may include applying a first block copolymer over the polarity switching layer, where the first block copolymer includes a first polar region and a first non-polar region with a first pitch, and a chemical difference between the exposed region of the polarity switching layer and the unexposed region of the polarity switching layer allows for directed self-assembly of the first non-polar region and the first polar region at the first pitch. In an embodiment, the method may further include selectively removing either the first polar region or the first non-polar region to form a first patterned mask over the polarity switching layer. In an embodiment, the method may further include patterning the polarity switching layer with an etching process using the first patterned mask. In an embodiment, the method may further include applying a polymer brush in an opening through the polarity switching layer and the first patterned mask, and applying a second block copolymer over the first block copolymer and the polymer brush. In an embodiment, the second block copolymer is annealed to drive directed self-assembly of a second polar region and a second non-polar region with a second pitch that is smaller than the first pitch. In an embodiment, the method may further include removing the second polar region or the second non-polar region to form a second patterned mask over the polarity switching layer.

Embodiments described herein relate to a method that includes exposing a polarity switching layer with extreme ultraviolet (EUV) radiation to form an exposed region and an unexposed region, where the polarity switching layer has a thickness that is less than 25 nm. In an embodiment, the method may further include applying a block copolymer over the polarity switching layer, and annealing a portion of the block copolymer with a laser to allow for a directed self-assembly process of the portion of the block copolymer to segregate a polar region of the block copolymer from a non-polar region of the block copolymer. In an embodiment, the exposed region and the unexposed region have chemical differences that provide a template to enable the directed self-assembly process. In an embodiment, the method may further include removing the polar region or the non-polar region to form a patterned mask over the polarity switching layer. In an embodiment, the method may further include etching the polarity switching layer to form a patterned polarity switching layer using the patterned mask.

### BRIEF DESCRIPTION OF THE DRAWINGS

FIG. 1A is a cross-sectional illustration of a device with a patterning layer and a polarity switching layer over the patterning layer, in accordance with an embodiment.

FIG. 1B is a chemical structure of a polarity switching layer, in accordance with an embodiment.

FIG. 1C is a cross-sectional illustration of the device after the polarity switching layer is exposed to form exposed regions and unexposed regions, in accordance with an embodiment.

FIG. 1D is a cross-sectional illustration of the device after a block copolymer is formed over the polarity switching layer, in accordance with an embodiment.

FIG. 1E is a cross-sectional illustration of the device after the block copolymer is annealed to drive selective segregation of the block copolymer into a polar region and a non-polar region, in accordance with an embodiment.

FIG. 1F is a chemical structure of the block copolymer, in accordance with an embodiment.

FIG. 1G is a cross-sectional illustration of the device after one of the blocks is removed and the polarity switching layer is removed, in accordance with an embodiment.

FIG. 1H is a cross-sectional illustration of the device after the patterning stack is patterned using the overlying block copolymer as a mask, in accordance with an embodiment.

FIG. 1I is a process flow diagram that depicts a process for patterning a patterning stack with a block copolymer, in accordance with an embodiment.

FIG. 2A is a cross-sectional illustration of a device with an exposed polarity switching layer over a patterning stack on a substrate, in accordance with an embodiment.

FIG. 2B is a cross-sectional illustration of the device after a block copolymer is deposited over the polarity switching layer, in accordance with an embodiment.

FIG. 2C is a cross-sectional illustration of the device after the block copolymer is annealed to drive a segregation of polar regions from non-polar regions within the block copolymer, in accordance with an embodiment.

FIG. 2D is a cross-sectional illustration of the device after one of the regions of the block copolymers and the underlying polarity switching layer is removed, in accordance with an embodiment.

FIG. 2E is a cross-sectional illustration of the device after a polymer brush is deposited in openings through the block copolymer and the polarity switching layer, in accordance with an embodiment.

FIG. 2F is a cross-sectional illustration of the device after a second block copolymer is deposited over the polymer brush, in accordance with an embodiment.

FIG. 2G is a cross-sectional illustration of the device after the second block copolymer is annealed to drive segregation into polar regions and non-polar regions that have a pitch that is smaller than the pitch of the first block copolymer, in accordance with an embodiment.

FIG. 2H is a cross-sectional illustration of the device after one of the regions of the second block copolymer layer are removed and the pattern is transferred into an underlying layer, in accordance with an embodiment.

FIG. 2I is a process flow diagram that describes a process for patterning a patterning layer using a pitch scaling block copolymer process, in accordance with an embodiment.

FIG. 3A is a cross-sectional illustration of a laser treatment process that is configured to selectively anneal a block copolymer in order to selectively drive polar region and non-polar region segregation of the block copolymer, in accordance with an embodiment.

FIG. 3B is a cross-sectional illustration of a global heating tool that may be used to accurately control annealing of the block copolymer, in accordance with an embodiment.

FIG. 4 illustrates a block diagram of an exemplary computer system that may be used in conjunction with a processing tool, in accordance with an embodiment.

### DETAILED DESCRIPTION

Embodiments described herein include processes for patterning a polarity switching layer using directed self-assembly (DSA) with high chi block copolymers (BCPs). In the following description numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, advances in extreme ultraviolet (EUV) lithography equipment and the demand for smaller feature sizes are driving the industry towards the use of thinner EUV resist layers. Accordingly, embodiments disclosed herein may include the use of directed self-assembly (DSA) that leverages high chi block copolymers in order to implement pattern rectification of pattern line edge roughness after printing in combination with enabling the selection of a desired pattern tone of sufficient thickness and etch contrast to enable high quality pattern transfer.

In an embodiment, a block copolymer layer is deposited over a polarity switching layer (or other photosensitive layer) that has been exposed to EUV radiation to form exposed regions and unexposed regions. Annealing the block copolymer drives a DSA process that results in the formation of a polar region and a non-polar region that are arranged in an alternating pattern. More particularly, the pattern of the non-polar region and polar region is aligned with the exposed regions and the unexposed regions of the polarity switching layer. For example, a chemical difference between the exposed regions and the unexposed regions at the surface of the polarity switching layer may enable the DSA process.

Thereafter, chemical differences between the polar region and the non-polar region allow for one of the blocks to be preferentially etched, and the remaining block remains behind as a patterning mask for the polarity switching layer and the underlying layers. As such, the etch selectivity and/or thickness of the polarity switching layer is less critical to pattern transfer into an underlying hardmask layer. Further, since the block copolymer is used as the mask to etch the polarity switching layer, the polarity switching layer does not need to be developed in the traditional sense. Instead, the etching process described herein allows for the well-defined edges of the block copolymer to be transferred into the polarity switching layer during the etching process. As such, high dosages are not needed in order to generate the desired pattern properties.

It is to be appreciated that such a template for the block copolymer is different than previous attempts to use block copolymers in lithography processes. Typically, the polarity switching layer is exposed and developed to expose portions of an underlying layer. The exposed portions of the underlying layer are then treated (e.g., oxidized), and the polarity switching layer is removed. Thereafter, the underlying layer includes treated regions and untreated regions that can be used as the template for the DSA process of the block copolymer. That is, the polarity switching layer is still developed to form the pattern. Accordingly, the polarity switching layer still suffers from the same issues with respect to thin polarity switching thicknesses described in greater detail herein.

Accordingly, embodiments disclosed herein have lower demands on the polarity switching material. For example, the thickness of the polarity switching layer is not as critical since the polarity switching layer is only being used as a template for the block copolymer. Additionally, the chemical reactions, diffusion of species, etc. within the polarity switching layer are not directly driving the sidewall properties. Instead of needing to engineer a polarity switching material that is developable with good properties at low doses, embodiments allow for the patterning of the polarity switching layer to be done through a mask (e.g., through a patterned block copolymer mask). As such, the simpler task of designing a DSA process that allows for good segregation between polar regions and non-polar regions of the block copolymer can be used in order to the define high quality patterning properties, such as excellent LER, LWR, CDU, and/or the like, with thin EUV polarity switching layers, such as those under 25 nm or those under 15 nm.

Additionally, embodiments disclosed herein allow for pitch division through the use of multiple block copolymer layers. In such an embodiment, the first block copolymer is formed and segregated into polar regions and non-polar regions using the exposed EUV polarity switching layer as a template. One of the polar or non-polar regions are then removed and replaced with a polymer brush. The second block copolymer can then be added over the first block copolymer and the polymer brush. The second block copolymer can be designed so that the second block copolymer segregates to form an alternating pattern of polar regions and non-polar regions with a pitch that is smaller than the pitch of the polar regions and the non-polar regions of the first block copolymer.

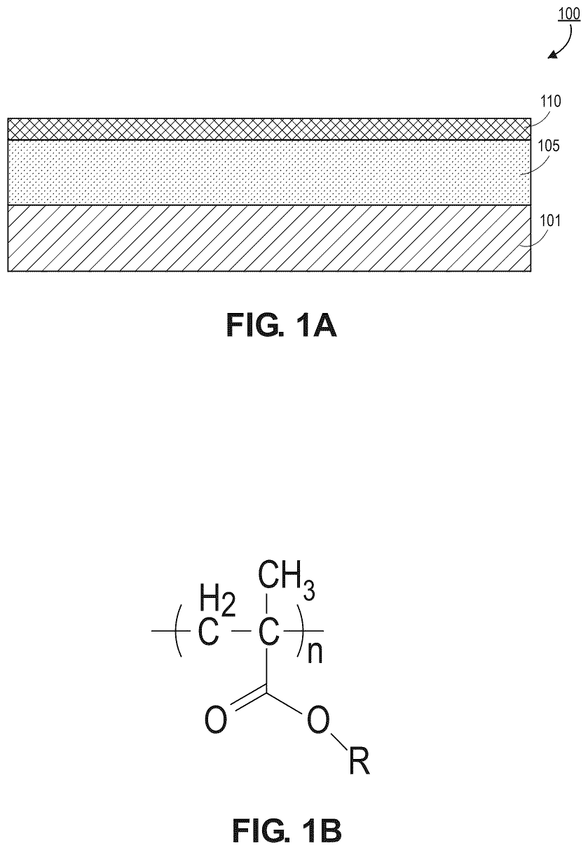

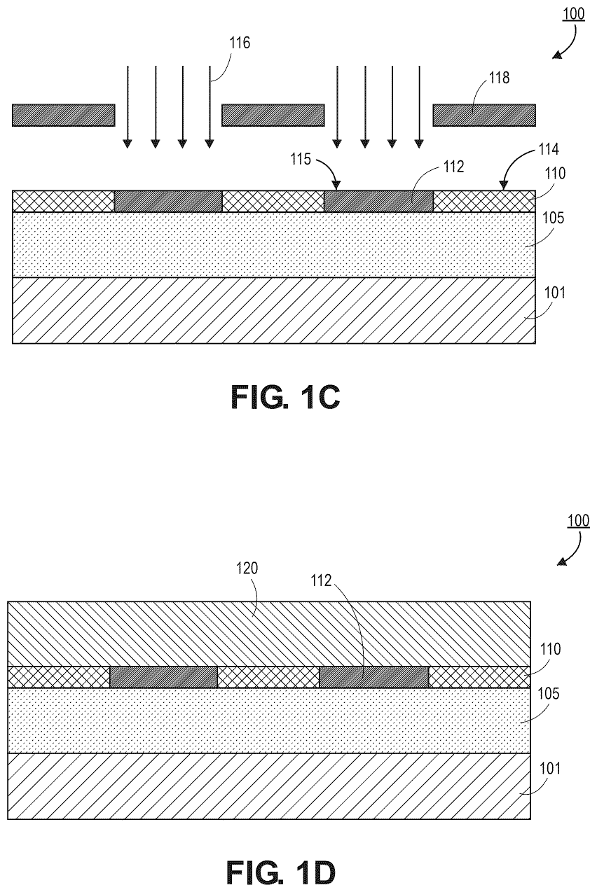

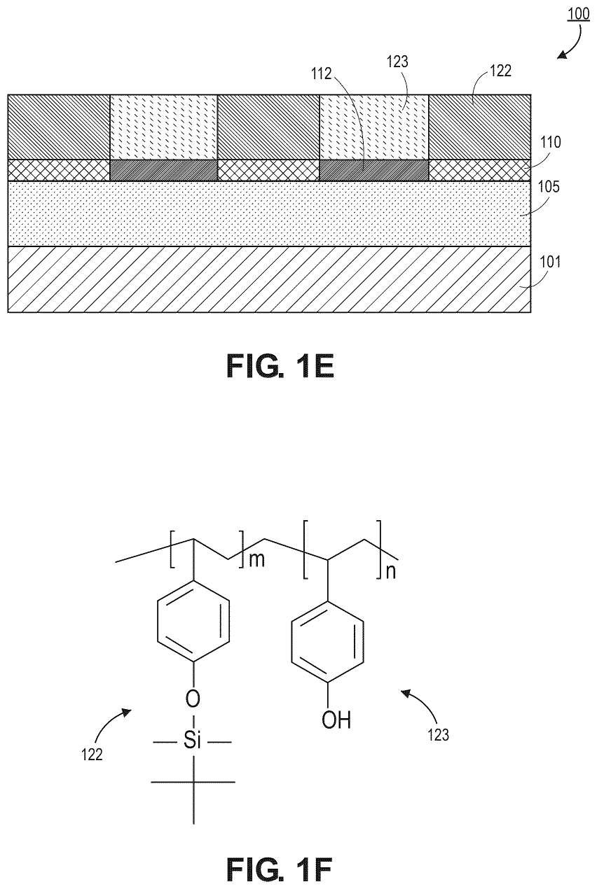

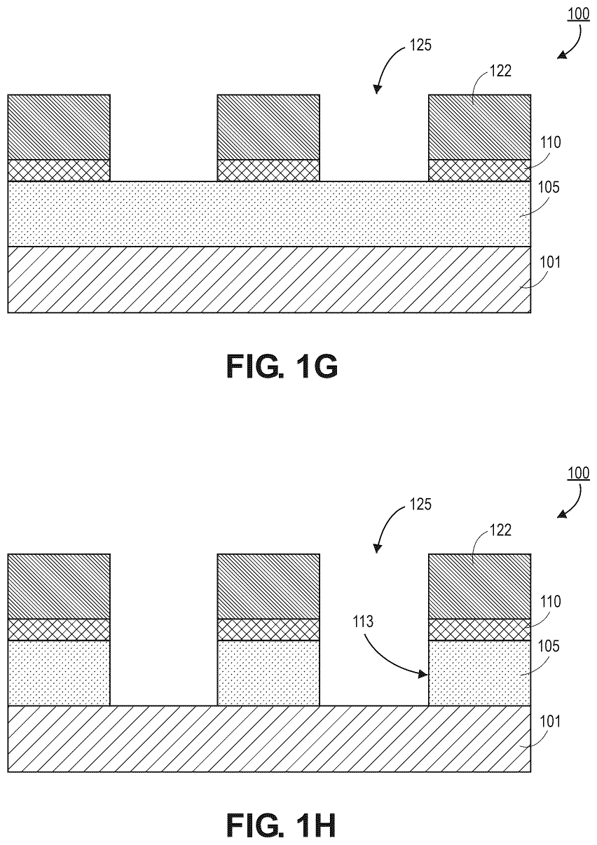

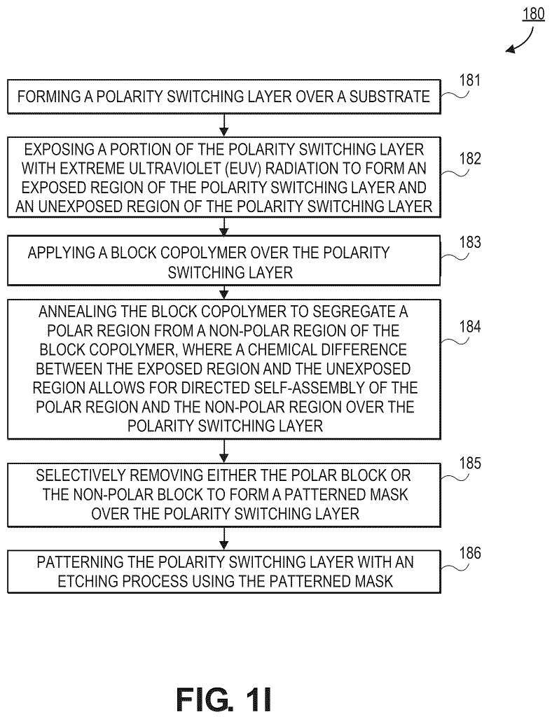

Referring now to FIGS. 1A-1H, a series of illustrations depicting a process for patterning a polarity switching layer using a DSA process enabled by a block copolymer is shown, in accordance with an embodiment.

Referring now to FIG. 1A, a cross-sectional illustration of a portion of a device 100 is shown, in accordance with an embodiment. In an embodiment, the device 100 may include a patterning stack 105 and a polarity switching layer 110 over the patterning stack 105. The polarity switching layer 110 and the patterning stack 105 may be provided over a substrate 101. In an embodiment, the patterning stack 105 may include one or more layers suitable for transferring a pattern formed into the polarity switching layer 110 into the underlying substrate 101. For example, the patterning stack 105 may comprise multiple layers, such as a silicon hardmask layer, a carbon hardmask layer, an antireflective coating, and/or the like. In some embodiments, the patterning stack 105 may comprise underlayer (not individually shown). In an embodiment, the underlayer may comprise a material that is sensitive to extreme ultraviolet (EUV) radiation or deep ultraviolet (DUV) radiation in order to generate species (e.g., elements, molecules, electrons, etc.) that can diffuse into the overlying polarity switching layer 110 in order to participate in the solubility switch reaction. In an embodiment, the underlayer may be deposited with a dry deposition process (e.g., chemical vapor deposition (CVD), atomic layer deposition (ALD), or the like). Though, in other embodiments the underlayer may be omitted.

In an embodiment, the polarity switching layer 110 may comprise a material that reacts when exposed to EUV and/or DUV radiation in order to generate a solubility switch. In a particular embodiment, the polarity switching layer 110 may comprise a metal oxide resist (MOR) material. The polarity switching material may also include an organometallic oxide material. In an embodiment, a MOR material may comprise a photoresist material with one or more metals (e.g., tin, indium, hafnium, zinc, zirconium, or any combination thereof). The MOR material may also comprise an organotin-oxo photoresist material, an organoindium-oxo photoresist material, or the like. In other embodiments the polarity switching layer 110 may comprise a chemically amplified resist (CAR). In some embodiments, the polarity switching layer 110 may be considered a resist material. Embodiments disclosed herein allow for the polarity switching layer 110 to have a thickness that is approximately 25 nm or less, or approximately 15 nm or less.

Referring now to FIG. 1B, a generic chemical structure for a polarity switching layer 110 is shown, in accordance with an embodiment. As shown, the chemical structure comprises an R-group that may represent any chemical group that is reactive to DUV and/or EUV radiation to implement a polarity shift. For example, a hydrophilic sulfonium salt may be part of the R group, and upon exposure to DUV and/or EUV radiation, the R group is altered to be comprise a hydrophobic sulfur component. Similarly, a spiropyran may also be used as part of the R-group. In such an embodiment, the spiropyran bond is UV cleavable and breaking the bond may trigger a transition from a hydrophobic to hydrophilic surface. In an embodiment, the spiropyran may be anchored to a surface of the polarity switching layer 110, or the spiropyran may be integrated into the polymer material of the polarity switching layer 110.

Referring now to FIG. 1C, a cross-sectional illustration of the device 100 after the polarity switching layer 110 is exposed to form exposed regions 112 is shown, in accordance with an embodiment. The unexposed regions of the polarity switching layer 110 may sometimes be referred to as “unexposed regions 110” in some embodiments. In an embodiment, the polarity switching layer 110 may be selectively exposed with EUV and/or DUV radiation 116. For example, the radiation 116 may be passed through a reticle or a mask 118, the radiation 116 may be applied with direct laser writing, or the like. In an embodiment, the exposed regions 112 may be a latent image that has a desired pattern within the polarity switching layer 110. For example, the exposed regions 112 may have the pattern of lines to form traces in the underlying layers (e.g., the patterning stack 105 and the underlying substrate 101). In an embodiment, the exposed region 112 may refer to a region of the polarity switching layer 110 that has undergone a chemical change (e.g., a cross-linking reaction, deprotection reaction, or the like) in order to alter the solubility with respect to a developing chemistry.

Of particular interest to embodiments disclosed herein, the selective exposure may result in a chemical contrast between a surface 115 of the exposed region 112 and a surface 114 of the unexposed region 110. For example, the chemical contrast may refer to a difference in the polarity of the surfaces 115 and 114. In one embodiment, one of the surfaces 115 or 114 may be polar, and the other of the surfaces 115 or 114 may be non-polar. As used herein, “polar and non-polar” may refer to a relative polarity difference between the surfaces 115 and 114. That is, the “non-polar surface” may have some amount of polarity, though the “non-polar surface” has a lower polarity than the “polar surface”.

In the case of a MOR polarity switching material, the exposed region 112 may have a high concentration of OH groups at the surface 115 of the exposed region 112, and the unexposed region 110 may retain R-groups of the metal clusters at the surface 114 of the unexposed region 110. In the case of a CAR, the exposed region 112 may have a surface 115 with a high concentration of esters while the unexposed region 110 comprises an acid and/or hydroxyl side group dominated surface 114 and/or an oxygen rich surface 114. In some instances the exposed region 112 may be hydrophilic and the unexposed region 110 may be hydrophobic.

The surfaces 114 and 115 with alternating polarities provides a template for a block copolymer layer to be applied and segregated through a DSA process. For example, the block copolymer may have a polar region and a non-polar region that self-assembles in response to the template provided by the surfaces 114 and 115.

Referring now to FIG. 1D, a cross-sectional illustration of the device after a block copolymer layer 120 is applied over the exposed regions 112 and the unexposed regions 110 is shown, in accordance with an embodiment. In an embodiment, the block copolymer layer 120 may be applied as a liquid and distributed over the device 100 with a spinning process (e.g., a spin coating process). In an embodiment, the block copolymer layer 120 may comprise a high chi block copolymer in order to improve the ability to segregate the block copolymer layer into polar regions and non-polar regions.

As deposited, the block copolymer layer 120 may not have sufficient energy to distribute as an ordered layer. As such, some embodiments may include an annealing process in order to drive the DSA process to provide alternating blocks 123 and 122, as shown in FIG. 1E.

In an embodiment, the blocks 123 may be polar regions 123, and the blocks 122 may be non-polar regions 122. Accordingly, the polar regions 123 will segregate over the polar regions and the non-polar regions 122 will segregate over the non-polar regions. For example, polar regions 123 may be provided over the exposed regions 112, and the non-polar regions 122 may be provided over the non-polar regions. An example of one suitable block copolymer is shown in FIG. 1F. As shown, the block 123 may comprise a polar —OH termination, and the block 122 may comprise a non-polar structure that comprises an inorganic group, such as silicon or the like. In an embodiment, silicon provides a lower etch rate for the block 123 in order to provide etch selectivity with respect to the block

In other embodiments, the block copolymer 120 may have a general structure such as:

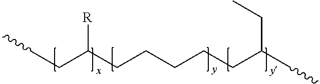

where R comprises an arene compound, such as one or more of:

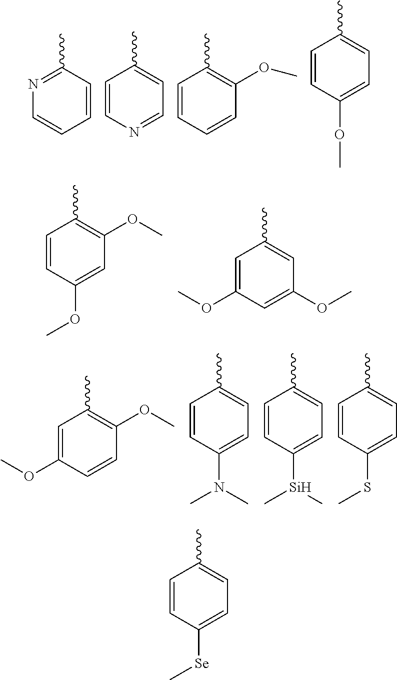

In a particular embodiment, the block copolymer 120 may comprise a hydroxystyrene, such as one or more of poly(hydroxystyrene-b-butadiene), poly(hydroxystyrene-b-hydrogenated butadiene), poly(vinylpyridine-b-butadiene), or poly(vinylpyridine-b-hydrogenated butadiene).

In an embodiment, the block copolymer 120 may be chosen to provide a desired tone for the patterning process. That is, embodiments allow for the generation of either a positive tone resist or a negative tone resist through the selection of the proper block copolymer 120. For example, a chemical structure that enhances etch resistance (e.g., a benzene ring or other arene structure) may be added to the polar region 123 or the non-polar region, depending on which tone is desired. For example, when the polar region 123 has an etch resistant structure, the non-polar region 122 will be preferentially etched to provide a negative tone resist, and when the non-polar region 122 has an etch resistant structure, the polar region 123 will be preferentially etched to provide a positive tone resist.

In an embodiment, a block copolymer 120 useful for a positive tone resist may comprise a non-polar region 122 that includes polystyrene and a polar region 123 that includes poly(methyl methacrylate) (PMMA). In an embodiment, a block copolymer 120 that is useful for a negative tone resist may comprise a non-polar region 122 that is a poly-hydrocarbon with a non-arene group (e.g., an alkyl group), and the polar region 123 may comprise a poly(hydroxystyrene), such as one or more of:

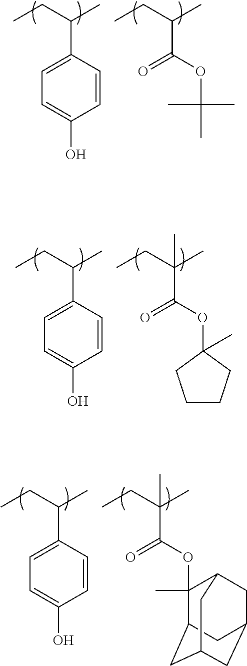

As can be appreciated, a highly efficient process for segregating the block copolymer 120 into the polar regions 123 and the non-polar regions 122 is beneficial for improving the speed of the process, as well as improving the patterning properties. Accordingly, some embodiments may select a block copolymer 120 with a high Flory-Huggins interaction parameter chi (x). High chi block copolymers also allow for small feature sizes that enable improved scaling of the line-space dimensions used in advanced semiconductor manufacturing environments.

In an embodiment, the annealing process may include any suitable heating of the block copolymer 120. In some embodiments, localized rapid heating of portions of the block copolymer 120 may be used to drive localized DSA of the blocks 122 and 123. For example, a laser heating process may be used to heat portions of the block copolymer 120 (e.g., with an area of approximately 1.0 mm² or larger). Such localized annealing may be beneficial when the DSA block copolymer 120 structure is not needed across an entire wafer and/or if the DSA block copolymer 120 structure is needed within a defined area of a die. In such embodiments, subsequent etching may use the assembled pattern to transfer the fine features into an underlying layer while the unassembled area (that was not annealed) may act as a blocking mask.

In other embodiments, a global annealing process may be used to anneal the entire block copolymer 120. For example, a lamp-based thermal irradiation of the block copolymer 120 may be used. In some instances the wafer may be rotated below the lamps to improve processing uniformity. Such thermal irradiation of the block copolymer 120 may prove to be more efficient than traditional hot plate based annealing processes.

Referring now to FIG. 1G, a cross-sectional illustration of the portion of the device 100 after the block copolymer 120 is patterned in order to form a patterned mask over the polarity switching layer 110 is shown, in accordance with an embodiment. In the illustrated embodiment, the polar region 123 is removed to form an opening 125 through the block copolymer 120. The polar region 123 may be removed with an etching process. However, as noted above, a negative tone resist may be manufactured by choosing a polar region 123 that has a higher etch resistance than the non-polar region 122. In such an embodiment, the unexposed regions of the polarity switching layer 110 are exposed after the block copolymer patterning process. In some embodiments, the etching process may include a high angle etch (e.g., between approximately 60° and approximately 80° relative to the substrate 101). In some embodiments, a high angle etch may provide performance benefits compared to traditional etching conditions.

Referring now to FIG. 1H, a cross-sectional illustration of the portion of the device 100 after a pattern of the block copolymer layer 120 is transferred into the polarity switching layer 110 is shown, in accordance with an embodiment. In an embodiment, the polarity switching layer 110 may be patterned with an etching process that etches the polarity switching layer 110 through the opening 125 in the mask of the block copolymer layer 120. That is, patterning of the polarity switching layer 110 is not entirely dependent on the chemical reactions induced by the EUV and/or DUV exposure. Instead, the opening 125 defines the pattern in the polarity switching layer 110. Accordingly, the sidewall 113 may be straighter than a traditional resist development process. This provides better LER, LWR, and/or the like for the polarity switching layer 110 without the need for high EUV and/or DUV dosages.

In an embodiment, the polarity switching layer 110 may be etched with any suitable etching chemistry through a dry etching process. In the case of a MOR polarity switching layer 110, an HBr based chemistry, or the like may be used. In the case of a CAR polarity switching layer 110, a chemistry comprising one or more of O₂, CF₄, or any other suitable CAR etching chemistry may be used.

After the polarity switching layer 110 is patterned, the pattern of the opening 125 may be transferred into the underlying patterning stack 105 with one or more etching processes. In some embodiments, the etching for the polarity switching layer 110 and the patterning stack 105 may be implemented in a single chamber. This is beneficial compared to existing solutions that require a separate developing chamber in order to develop the resist layer using traditional processes. Further, it is to be appreciated that the etch resistance of the polarity switching layer 110 does not need to be high since the overlying non-polar region 122 of the block copolymer 120 protects the polarity switching layer 110.

Referring now to FIG. 1I, a flow diagram that depicts a process 180 for patterning a substrate with a high chi block copolymer is shown, in accordance with an embodiment. In an embodiment, the process 180 may include operations, materials, and/or the like similar to any of those described herein with respect to FIGS. 1A-1H.

In an embodiment, the process 180 may begin with operation 181, which comprises forming a polarity switching layer over the substrate. In an embodiment, the polarity switching layer may be similar to any of the polarity switching layers described in greater detail herein. For example, the polarity switching may may comprise a MOR material or a CAR material. In an embodiment, a thickness of the polarity switching layer may be approximately 25 nm or less or approximately 15 nm or less. The polarity switching layer may be deposited over the substrate with a dry deposition process, a spin coating process, or any other suitable process. In an embodiment, a patterning stack may also be provided between the substrate and the polarity switching layer.

In an embodiment, the process 180 may continue with operation 182, which comprises exposing a portion of the polarity switching layer with EUV radiation (and/or DUV radiation) to form an exposed region of the polarity switching layer and an unexposed region of the polarity switching layer. In an embodiment, the exposure may be made through a mask or a reticle. Direct laser writing may also be used for the exposure process. In an embodiment, the exposure may be a relatively low dose exposure since the exposure just needs to generate a chemical contrast between the surfaces of the exposed region and the unexposed region.

In an embodiment, the process 180 may continue with operation 183, which comprises applying a block copolymer over the polarity switching layer. The block copolymer may be applied with a spin coating process or the like. The block copolymer may be a high chi block copolymer. For example, the block copolymer may be similar to any of the block copolymers described in greater detail herein.

In an embodiment, the process 180 may continue with operation 184, which comprises annealing the block copolymer to segregate a polar region from a non-polar region of the block copolymer. In an embodiment, a chemical difference (e.g., a polar surface versus a non-polar surface) between the exposed region and the unexposed region of the polarity switching layer allows for a DSA process of the polar region and the non-polar region over the polarity switching layer. In an embodiment, the block copolymer comprises a polar region and a non-polar region. In an embodiment, the annealing may be a localized anneal (e.g., with a laser) or a global annealing (e.g., with thermal lamps). In some embodiments, the polar regions are etch resistant to provide a negative tone polarity switching, and in other embodiments the non-polar regions are etch resistant to provide a positive tone polarity switching.

In an embodiment, the process 180 may continue with operation 185, which comprises selectively removing either the polar region or the non-polar region to form a patterned mask over the polarity switching layer. In an embodiment, the removal of one of the polar region or the non-polar region may be done with an etching process. In an embodiment, the patterned mask may have an opening that forms a line/space pattern. In an embodiment, the etching process may be a high angle etching process (e.g., between approximately 60° and approximately 80° relative to the substrate).

In an embodiment, the process 180 may continue with operation 186, which comprises patterning the polarity switching layer with an etching process using the patterned mask. The etching process may be a dry etching process. Any of the etching chemistries for MOR materials or CAR materials described herein may be used to etch the polarity switching layer. The use of a mask during the etching process allows for improved LER, LWR, and/or CDU compared to traditional resist development processes which rely on the diffusion and chemical reactions through the thickness of the polarity switching layer. Improved patterning performance may also obtained without increasing the dose of the EUV radiation and/or DUV radiation during exposure. Additionally, the thickness of the polarity switching layer can be reduced without negatively impacting patterning performance.

After the polarity switching layer is patterned, the pattern defined by the opening can be transferred into the layers below the polarity switching layer, such as a patterning stack and/or a substrate. Further, the etching process to pattern the polarity switching layer may be implemented in the same chamber as the etching process (or processes) used to etch the underlying layers. As such, fewer chambers and chamber transfers are needed to execute the process. As such, the throughput and cost of the process can be reduced.

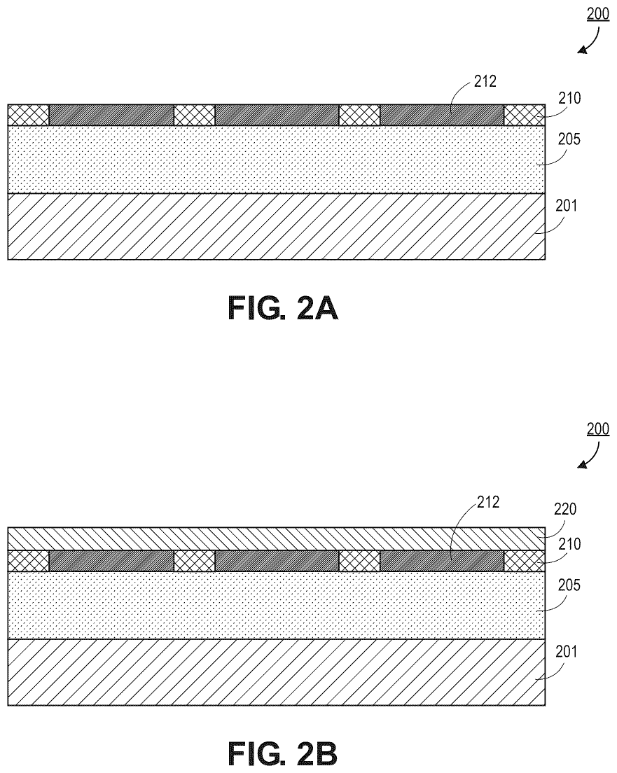

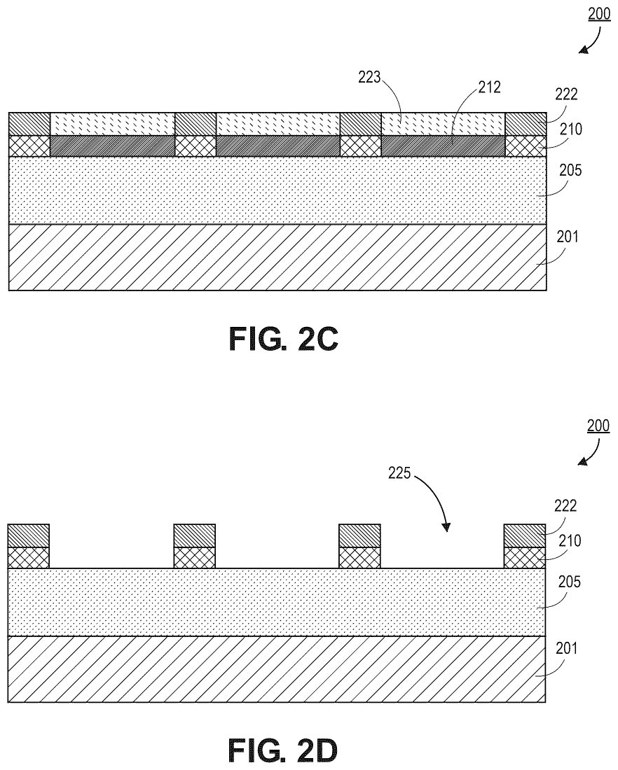

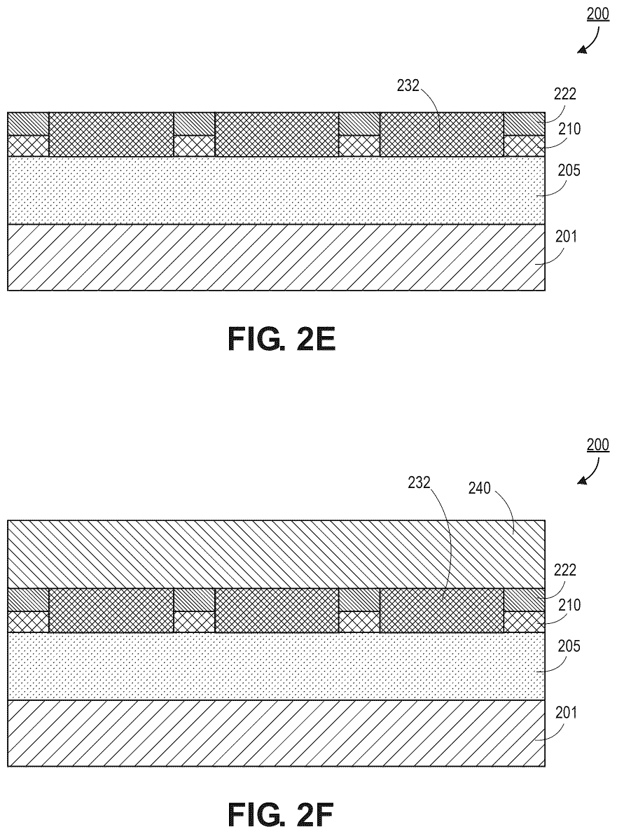

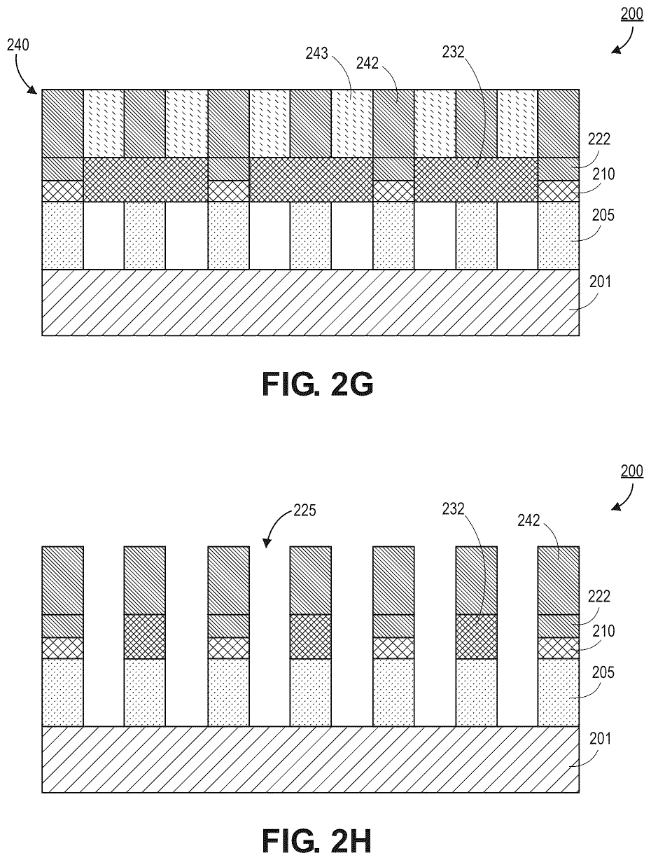

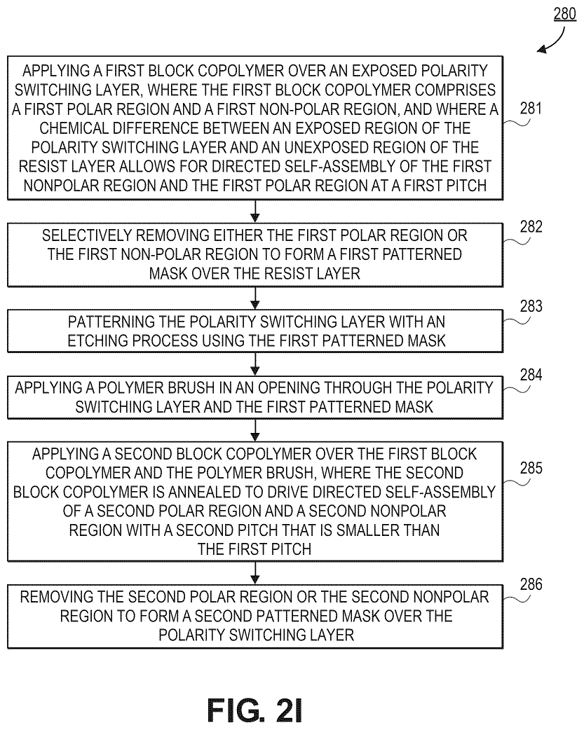

Referring now to FIGS. 2A-2H, a series of cross-sectional illustrations that depict a process for patterning a substrate with a polarity switching layer and a pair of block copolymer layers is shown, in accordance with an embodiment. In an embodiment, the pair of block copolymer layers may be used to implement a pitch division process that allows for even finer pitched features to be formed.

Referring now to FIG. 2A, a cross-sectional illustration of a portion of a device 200 is shown, in accordance with an embodiment. In an embodiment, the device 200 may comprise a substrate 201 with a patterning stack 205 and a polarity switching layer 210 over the substrate 201. In an embodiment, the polarity switching layer 210 may be similar to any of the polarity switching layers described in greater detail herein. As shown, the polarity switching layer 210 has been exposed to DUV and/or EUV radiation in order to form exposed regions 212 and unexposed regions 210. In the illustrated embodiment, the exposed regions 212 may be wider than the unexposed regions 210.

Referring now to FIG. 2B, a cross-sectional illustration of the portion of the device 200 after a first block copolymer layer 220 is applied over the polarity switching layer 210 is shown, in accordance with an embodiment. In an embodiment, the first block copolymer layer 220 may be similar to any of the block copolymer layers described in greater detail herein. In an embodiment, the first block copolymer layer 220 may be applied with a spin coating process or the like.

Referring now to FIG. 2C, a cross-sectional illustration of the portion of the device 200 after the first block copolymer layer 220 is annealed to form polar regions 223 and non-polar regions 222 is shown, in accordance with an embodiment. The annealing process may include a localized anneal (e.g., a laser anneal) or a global anneal (e.g., thermal irradiation from an array of lamps). As shown, the polar regions 223 segregate over the exposed regions 212 and the unexposed regions 210, similar to embodiments described in greater detail herein. In an embodiment, the non-polar regions 222 may be cross-linked. In an embodiment, the non-polar regions 222 and the polar regions 223 may have a first pitch.

Referring now to FIG. 2D, a cross-sectional illustration of the portion of the device 200 after the polar regions 223 are removed with an etching process is shown, in accordance with an embodiment. The polar regions 223 may be removed with a suitable etching process or the like to form openings 225. The remaining non-polar regions 222 may function as a mask to transfer the pattern of the openings into the underlying polarity switching layer 210.

Referring now to FIG. 2E, a cross-sectional illustration of the portion of the device 200 after a polymer brush 232 is applied into the openings 225 is shown, in accordance with an embodiment. In an embodiment, the polymer brush 232 may comprise monomers used in the overlying second block copolymer (added in a subsequent processing operation) is suitable to drive the desired lamellae formation to enable the formation of line/space patterns. For example, the polymer brush 232 may comprise a hydroxy-terminated random copolymer of styrene and methyl methacrylate. In an embodiment, the mol fraction of styrene in the polymer brush may be controlled in order to drive the desired DSA process that enables low defect pitch division in an overlying second block copolymer.

Referring now to FIG. 2F, a cross-sectional illustration of the portion of the device 200 after the second block copolymer 240 is added over the non-poler regions 222 of the first block copolymer 220 and the polymer brush 232 is shown, in accordance with an embodiment. In an embodiment, the second block copolymer 240 may comprise a similar composition as the first block copolymer 220. The second block copolymer 240 may be applied with a spin coating process or the like.

Referring now to FIG. 2G, a cross-sectional illustration of the portion of the device 200 after the second block copolymer 240 is annealed to drive a DSA process is shown, in accordance with an embodiment. The annealing process may be a localized annealing process or a global annealing process. In an embodiment, the annealing process may result in the formation of segregated polar regions 243 and non-polar regions 242. As shown, the presence of the polymer brush 232 and the first layer non-polar regions 222 results in the DSA process producing alternating polar regions 243 and non-polar regions 242 at a second pitch that is smaller than the first pitch.

Referring now to FIG. 2H, a cross-sectional illustration of the portion of the device 200 after the polar regions 243 are removed and used as an etching mask to etch through the underlying layers. In an embodiment, the polar regions 243 are removed with an etching process that is selective to the non-polar regions 242. The non-polar regions 242 may then be used as a mask to etch through the polymer brush 232, the polarity switching layer 210, and the patterning stack 205. The openings 225 may then be transferred into the underlying substrate 201 with a subsequent etching process.

Referring now to FIG. 2I, a flow diagram that depicts a process 280 for patterning a substrate with a high chi block copolymer with a pitch division process is shown, in accordance with an embodiment. In an embodiment, the process 280 may include operations, materials, and/or the like similar to any of those described herein with respect to FIGS. 2A-2H.

In an embodiment, the process 280 may begin with operation 281, which comprises applying a first block copolymer over an exposed polarity switching layer. In an embodiment, the block copolymer may be applied with a spin coating process or the like. The block copolymer may be a high chi block copolymer. For example, the block copolymer may be similar to any of the block copolymers described in greater detail herein.

In an embodiment, the block copolymer is annealed to segregate a first polar region from a first non-polar region of the block copolymer. In an embodiment, a chemical difference (e.g., a polar surface versus a non-polar surface) between the exposed region and the unexposed region of the polarity switching layer allows for a DSA process of the first polar region and the first non-polar region at a first pitch. In an embodiment, the annealing may be a localized anneal (e.g., with a laser) or a global annealing (e.g., with thermal lamps).

In an embodiment, the process 280 may continue with operation 282, which comprises selectively removing either the polar region or the non-polar region to form a patterned mask over the polarity switching layer. In an embodiment, the removal of one of the polar region or the non-polar region may be done with an etching process. In an embodiment, the patterned mask may have an opening that forms a line/space pattern.

In an embodiment, the process 280 may continue with operation 283, which comprises patterning the polarity switching layer with an etching process using the patterned mask. The etching process may be a dry etching process. Any of the etching chemistries for MOR materials or CAR materials described herein may be used to etch the polarity switching layer.

In an embodiment, the process 280 may continue with operation 284, which comprises applying a polymer brush in an opening through the polarity switching layer and the first patterned mask. The polymer brush may be similar to any of the polymer brush materials described in greater detail herein. For example, the polymer brush may comprise monomers used in the first block copolymer. For example, the polymer brush may comprise styrene and/or methyl methacrylate.

In an embodiment, the process 280 may continue with operation 285, which comprises applying a second block copolymer over the first block copolymer and the polymer brush. In an embodiment, the second block copolymer is annealed to drive directed self-assembly of a second polar region and a second non-polar region with a second pitch that is smaller than the first pitch. In an embodiment, the interfacial energy between the layers drives the pitch division in the second block copolymer layer.

In an embodiment, the process 280 may continue with operation 286, which comprises removing the second polar region or the second non-polar region to form a second patterned mask over the polarization switching layer. In an embodiment, any suitable etching process may be used to selectively remove one type of region of the block copolymer.

After the second patterned mask is formed, the pattern defined by the openings in the second patterned mask can be transferred into the layers below the polarity switching layer, such as a polymer brush, the first block copolymer layer, the polarization switching layer, the patterning stack and/or a substrate. Further, the etching process to pattern the polarity switching layer may be implemented in the same chamber as the etching process (or processes) used to etch the underlying layers. As such, fewer chambers and chamber transfers are needed to execute the process. As such, the throughput and cost of the process can be reduced.

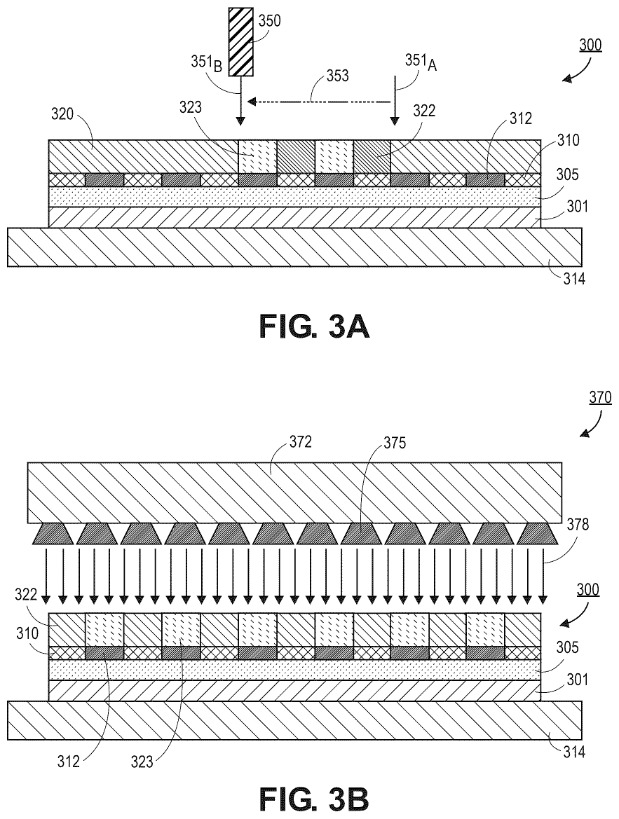

Referring now to FIG. 3A, a cross-sectional illustration of a laser annealing system 300 is shown, in accordance with an embodiment. In an embodiment, the system 300 may include a substrate pedestal 314, chuck, or the like. In an embodiment, a substrate 301 may be secured to the pedestal 314. The substrate 301 may be a semiconductor wafer, such as a silicon wafer, or the like. In an embodiment, a patterning stack 305 and a polarity switching layer 310 may be provided over the substrate. As shown, the polarity switching layer 310 may include exposed regions 312 that provide a chemical contrast that allows for DSA of a polar region 323 and a non-polar region 322 when the overlying block copolymer 320 is annealed.

As shown, a laser 350 may emit electromagnetic radiation 351 that locally anneals the block copolymer 320. In FIG. 3A, the laser 350 may start at a first location and emit electromagnetic radiation 351A, and the laser 350 may be scanned 353 across the block copolymer 320 towards a second location to emit electromagnetic radiation 351B. That is, the laser 350 may be displaceable across the surface of the block copolymer to provide localized DSA patterning of selected areas of the block copolymer 320.

Referring now to FIG. 3B, a cross-sectional illustration of a thermal annealing system 370 is shown, in accordance with an embodiment. In an embodiment, the thermal annealing system 370 may comprise a pedestal 314, chuck, or the like to support a substrate 301. A patterning stack 305 and a polarity switching layer 310 may be provided over the substrate 301. The polarity switching layer 310 may include exposed regions 312 that provide a chemical contrast that allows ordered segregation of polar regions 323 and non-polar regions 322 of a block copolymer in response to an annealing process.

In an embodiment, the thermal annealing system 370 may comprise an array of thermal lamps 375 that are coupled to a control system 372. The control system 372 may control the intensity of thermal irradiation 378 (e.g., infrared radiation) that is emitted by each of the lamps 375. In an embodiment, sensors (e.g., temperature sensors) may be included in the thermal annealing system 370 in order to monitor the temperature of the block copolymer to provide feedback control of the annealing process.

In an embodiment, the use of a plurality of individually controllable lamps 375 may allow for improved uniformity of the annealing process. In some embodiments, the uniformity of the annealing process may be improved by rotating the substrate 301 during the annealing process. For example, the pedestal 314 may be rotatable.

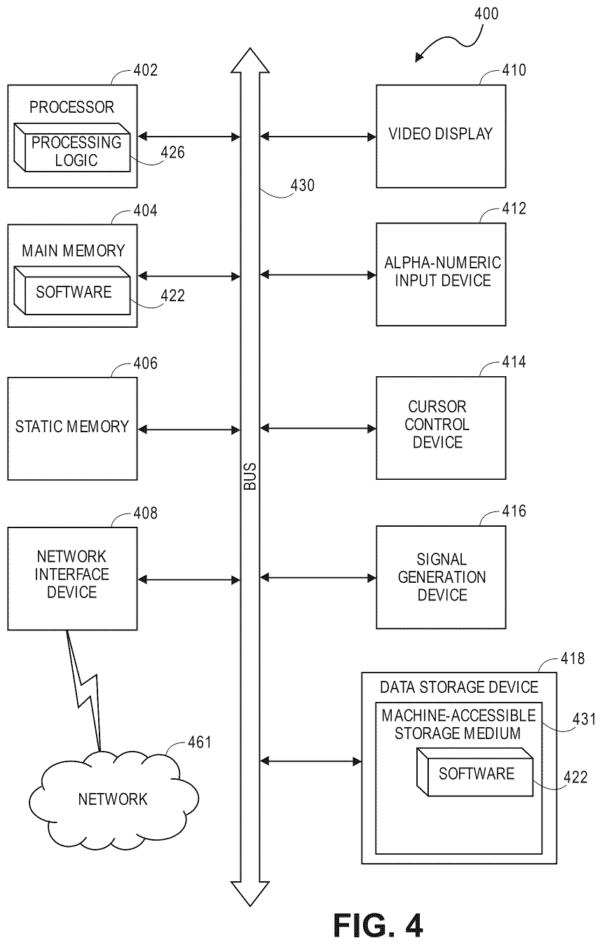

Referring now to FIG. 4, a block diagram of an exemplary computer system 400 of a processing tool is illustrated in accordance with an embodiment. In an embodiment, computer system 400 is coupled to and controls processing in the processing tool. Computer system 400 may be connected (e.g., networked) to other machines in a Local Area Network (LAN), an intranet, an extranet, or the Internet. Computer system 400 may operate in the capacity of a server or a client machine in a client-server network environment, or as a peer machine in a peer-to-peer (or distributed) network environment. Computer system 400 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 400, the term “machine” shall also be taken to include any collection of machines (e.g., computers) that individually or jointly execute a set (or multiple sets) of instructions to perform any one or more of the methodologies described herein.

Computer system 400 may include a computer program product, or software 422, having a non-transitory machine-readable medium having stored thereon instructions, which may be used to program computer system 400 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 400 includes a system processor 402, a main memory 404 (e.g., read-only memory (ROM), flash memory, dynamic random access memory (DRAM) such as synchronous DRAM (SDRAM) or Rambus DRAM (RDRAM), etc.), a static memory 406 (e.g., flash memory, static random access memory (SRAM), etc.), and a secondary memory 418 (e.g., a data storage device), which communicate with each other via a bus 430.

System processor 402 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 402 may also be one or more special-purpose processing devices such as an application specific integrated circuit (ASIC), a field programmable gate array (FPGA), a digital signal system processor (DSP), network system processor, or the like. System processor 402 is configured to execute the processing logic 426 for performing the operations described herein.

The computer system 400 may further include a system network interface device 408 for communicating with other devices or machines. The computer system 400 may also include a video display unit 410 (e.g., a liquid crystal display (LCD), a light emitting diode display (LED), or a cathode ray tube (CRT)), an alphanumeric input device 412 (e.g., a keyboard), a cursor control device 414 (e.g., a mouse), and a signal generation device 416 (e.g., a speaker).

The secondary memory 418 may include a machine-accessible storage medium 431 (or more specifically a computer-readable storage medium) on which is stored one or more sets of instructions (e.g., software 422) embodying any one or more of the methodologies or functions described herein. The software 422 may also reside, completely or at least partially, within the main memory 404 and/or within the system processor 402 during execution thereof by the computer system 400, the main memory 404 and the system processor 402 also constituting machine-readable storage media. The software 422 may further be transmitted or received over a network 461 via the system network interface device 408. In an embodiment, the network interface device 408 may operate using RF coupling, optical coupling, acoustic coupling, or inductive coupling.

While the machine-accessible storage medium 431 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method of patterning a polarity switching layer, comprising:
applying a block copolymer over the polarity switching layer;
annealing the block copolymer to generate a polar region and a non-polar region of the block copolymer, wherein a chemical difference between a first region of the polarity switching layer and a second region of the polarity switching layer allows for directed self-assembly of the polar region of the block copolymer and the non-polar region of the block copolymer over the polarity switching layer;
selectively removing either the polar region or the non-polar region to form a patterned mask over the polarity switching layer; and
patterning the polarity switching layer with an etching process using the patterned mask.

2. The method of claim 1, wherein the block copolymer is selectively annealed with a laser.

3. The method of claim 1, wherein the block copolymer is annealed with thermal lamps.

4. The method of claim 3, wherein the block copolymer is rotated during the annealing.

5. The method of claim 1, wherein the non-polar region of the block copolymer comprises an inorganic group to increase etch resistance of the non-polar region.

6. The method of claim 5, wherein the inorganic group comprises silicon.

7. The method of claim 1, wherein the polar region comprises an —OH group.

8. The method of claim 1, wherein the polarity switching layer is a chemically amplified resist (CAR) or a metal oxide resist (MOR).

9. The method of claim 1, wherein the polarity switching layer has a thickness of 25 nm or less.

10. The method of claim 1, wherein the chemical difference comprises a hydroxy and/or oxygen rich surface on an exposed region of the polarity switching layer and a relatively hydrophobic surface on an unexposed region of the polarity switching layer with respect to the exposed region.

11. The method of claim 1, wherein the etching process is a high angle etching process.

12. A method for patterning an exposed polarity switching layer that is over a substrate, wherein the exposed polarity switching layer comprises an exposed region and an unexposed region, the method comprising:
applying a first block copolymer over the polarity switching layer, wherein the first block copolymer comprises a first polar region and a first non-polar region with a first pitch, and wherein a chemical difference between the exposed region of the polarity switching layer and the unexposed region of the polarity switching layer allows for directed self-assembly of the first non-polar region and the first polar region at the first pitch;
selectively removing either the first polar region or the first non-polar region to form a first patterned mask over the polarity switching layer;
patterning the polarity switching layer with an etching process using the first patterned mask;
applying a polymer brush in an opening through the polarity switching layer and the first patterned mask;
applying a second block copolymer over the first block copolymer and the polymer brush, wherein the second block copolymer is annealed to drive directed self-assembly of a second polar region and a second non-polar region with a second pitch that is smaller than the first pitch; and
removing the second polar region or the second non-polar region to form a second patterned mask over the polarity switching layer.

13. The method of claim 12, wherein the polarity switching layer is a chemically amplified resist (CAR).

14. The method of claim 12, wherein the polarity switching layer is a metal oxide resist (MOR).

15. The method of claim 12, wherein the polarity switching layer has a thickness of 25 nm or less.

16. The method of claim 12, wherein the polymer brush is cross-linked.

17. The method of claim 12, wherein the first block copolymer is the same material as the second block copolymer.

18. A method, comprising:
exposing a polarity switching layer with extreme ultraviolet (EUV) radiation to form an exposed region and an unexposed region, wherein the polarity switching layer has a thickness that is less than 25 nm;
applying a block copolymer over the polarity switching layer;
annealing a portion of the block copolymer with a laser to allow for a directed self-assembly process of the portion of the block copolymer to segregate a polar region of the block copolymer from a non-polar region of the block copolymer, wherein the exposed region and the unexposed region have chemical differences that provide a template to enable the directed self-assembly process;
removing the polar region or the non-polar region to form a patterned mask over the polarity switching layer; and
etching the polarity switching layer to form a patterned polarity switching layer using the patterned mask.

19. The method of claim 18, wherein the polarity switching layer is a chemically amplified resist (CAR) or a metal oxide resist (MOR).

20. The method of claim 18, wherein the portion of the block copolymer is an area of approximately 1.0 mm² or more.
